(19) United States
(12) Patent Application Publication
(10) Pub. No.: US 2004/0048033 A1
(43) Pub. Date: Mar. 11, 2004

(54) Oled devices with improved encapsulation

(75) Inventors: Hagen Klausmann, Penang (MY); Bernd Fritz, Penang (MY)

Correspondence Address: Siemens Corporation, Attn: Elsa Keller, Legal Administrator, Intellectual Property Department, 186 Wood Avneue South, Iselin, NJ, 08830, US

(73) Assignee: Osram Opto Semiconductors (Malaysia) Sdn. Bhd.

(21) Appl. No.: 10/242,004

(22) Filed: Sep. 11, 2002

(51) Int. Cl. B32B 1/04; B32B 3/02; H01L 33/00; H01L 21/00; B05D 5/06; B05D 5/12; H01L 21/44; H01L 21/48; H01L 21/50

(52) U.S. Cl. 428/68; 428/76; 257/100; 257/88; 438/26; 438/28; 438/127; 427/58; 427/66

(57) ABSTRACT

A method of encapsulating organic devices including covering the active component with a getter layer. The getter layer comprises an alkaline earth metal. The getter layer serves to seal the active component and absorb surrounding moisture and gases.

### CROSS REFERENCE TO RELATED APPLICATIONS

This application is related to the following applications being filed concurrently:

U.S. Ser. No. ______, entitled “ENCAPSULATION FOR ORGANIC DEVICES” by Hagen Klausmann, Yuen Sin Lew, Hou Siong Tan and Hooi Bin Lim (Our Docket: 2002P13935US); U.S. Ser. No. ______, entitled “METHOD OF FABRICATING ELECTRONIC DEVICES” by Hagen Klausmann and Bernd Fritz (Our Docket: 2002P13934US); and U.S. Ser. No. ______, entitled “ACTIVE ELECTRONIC DEVICES” by Reza Stegamat (Our Docket: 2002P03163US). All of these applications are incorporated by reference herein in their entirety.

### FIELD OF THE INVENTION

The invention relates to the encapsulation of devices. More particularly, the invention relates to improved encapsulation of devices, such as organic light emitting diodes (OLEDs), which require protection from moisture, gases or other atmospheric elements.

### BACKGROUND OF THE INVENTION

Various types of devices may require hermetic sealing to protect the active components from atmospheric elements, such as moisture and/or gases. For example, devices which include organic active elements such as OLEDs require protection from moisture or gases. OLED devices can serve as displays for various types of consumer electronic products, such as automobile stereo displays, cellular phones, cellular smart phones, personal organizers, pagers, advertising panels, touch screen displays, teleconferencing and multimedia products, virtual reality products and display kiosks.

Referring to FIG. 1, a conventional OLED device is shown. The OLED device comprises a functional stack formed on a substrate 101. The functional stack comprises one or more organic functional layers 102 between two conductive layers (104 and 106) which serve as electrodes. The conductive layers are patterned to form rows of cathodes in a first direction and columns of anodes in a second direction. OLED cells are located in the active region where the cathodes and anodes overlap. Charge carriers are injected through the cathodes and anodes via bond pads 108 for recombination in the functional organic layers. The recombination of the charge carriers causes the functional layers of the cells to emit visible radiation.

Active components, such as the cathode or organic layers in organic devices are adversely impacted by potentially deleterious components such as water, oxygen and other gases. One approach is to hermetically encapsulate the device with a cap 110, sealing the cells. However, small amounts of such deleterious components can be trapped in the encapsulation during the sealing process. Additionally, such deleterious components may diffuse into the encapsulation over time. This can adversely impact the reliability of the OLED device.

To improve the sealing of the encapsulation, drying compounds 114 such as barium oxide, calcium oxide or sodium oxide, may be provided to absorb moisture within the encapsulation. However, these compounds react with water only, and cannot serve to remove residual gases such as oxygen. Reaction with water disadvantageously forms products that will adversely impact the device layers if they are not packaged and separated from the device layers. The packaging material poses an additional barrier through which water and gases have to permeate to be absorbed, hence reducing the speed and efficiency of absorption. Such restrictions will also lead to bulkier OLED devices and a reduction in efficiency of the fabrication process. Drying agents such as zeolite or silica gel absorb mainly water and not reactive gases. At high temperatures, these drying agents disadvantageously discharge the absorbed moisture into the internal space of the OLED device.

As evidenced from the foregoing discussion, it is desirable to provide an improved encapsulation for organic devices to protect the device layers from potentially deleterious components such as water and reactive gases.

### SUMMARY OF THE INVENTION

The invention relates to improved encapsulation of organic devices, particularly those which require protection from moisture and gases, such as OLED devices. A getter layer is provided to encapsulate the active components of the device and absorb surrounding moisture and gases. The getter layer comprises alkaline earth metals. In one embodiment, the getter layer comprises barium. In one embodiment, a cap is further provided to hermetically seal the device.

### BRIEF DESCRIPTION OF THE DRAWINGS

FIG. 1 shows a conventional OLED device; and

FIGS. 2-4 show OLED devices in accordance with different embodiments of the invention.

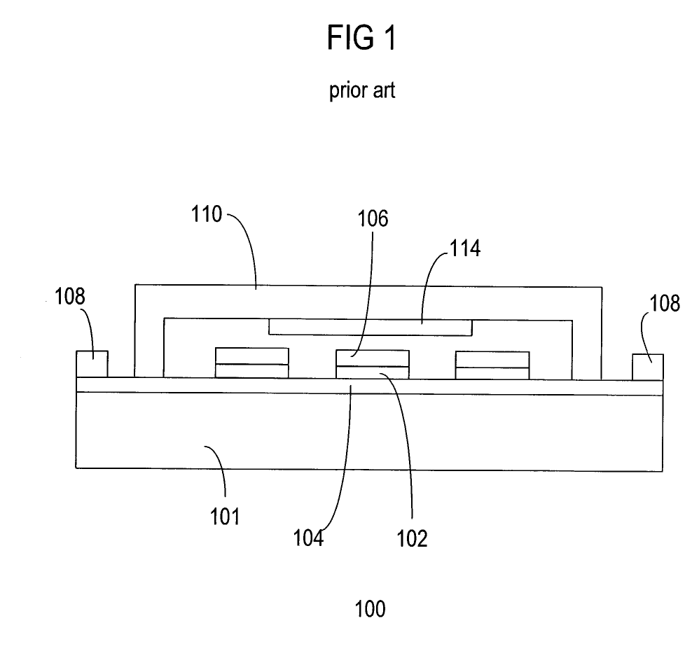

### PREFERRED EMBODIMENTS OF THE INVENTION

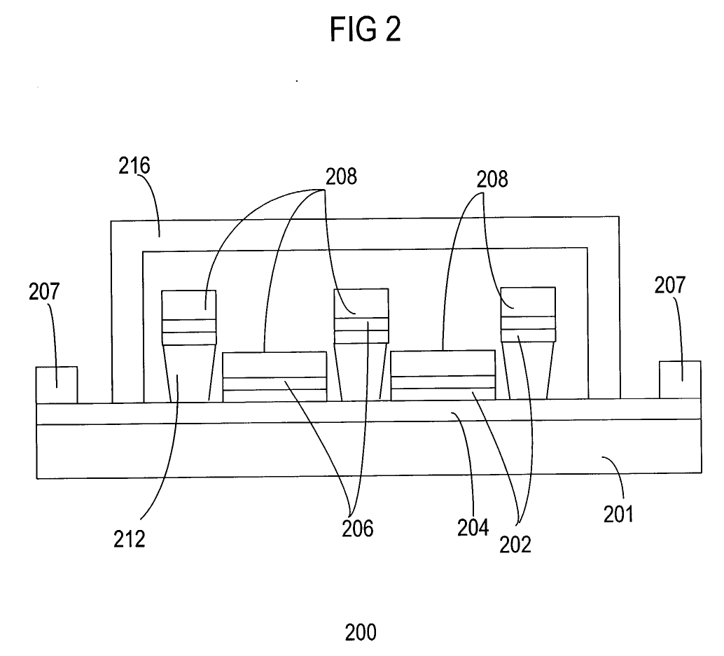

The invention relates to improved encapsulation of devices to protect the materials of the active component or components from atmospheric elements such as moisture and/or gases. FIG. 2 shows an OLED device 200 in accordance with one embodiment of the invention. In one embodiment, the device 200 comprises a substrate 201 having an active region defined thereon. The substrate comprises, for example, glass. Materials, such as silicon or other semiconductor materials, are also useful. To form flexible devices, materials such as plastics, can be used. Various other materials, which can provide sufficient mechanical stability for forming the device, are also useful.

The active region comprises one or more active components of the device. In one embodiment, the active components comprise organic materials which require protection from moisture and/or atmospheric gases. The organic materials, for example, are conductive polymers or molecules. The organic materials are used to form electronic components, such as transistors, to form circuitry for different electronic applications, such as sensors, receivers, displays, or other applications. Other types of materials, such as metals, may also require protection from atmospheric elements. The active components can be used to form various types of devices, such as electrical or electromechanical devices. Forming other types of devices is also useful.

In a preferred embodiment, the active region comprises one or more OLED cells for forming an OLED device. The OLED device can serve as a display or other purposes, such as lighting applications. In one embodiment, the substrate comprises a transparent substrate, such as glass or plastic. The substrate is typically about 0.4-1.1 mm thick. In one embodiment, the substrate comprises a flexible material, such as a plastic film for forming a flexible device. Various commercially available plastic films can be used to serve as the substrate. Such films, for example, include transparent poly(ethylene terephthalate) (PET), poly(butylene terephthalate) (PBT), poly(enthylene naphthalate) (PEN), polycarbonate (PC), polyimides (PI), polysulfones (PSO), and poly(p-phenylene ether sulfone) (PES). Polymeric materials advantageously enable fabrication of devices using a roll-to-roll process. Alternatively, materials such as ultra thin glass (e.g., thickness between 10-100 μm), a composite stack comprising glass and polymer or polymer films coated with inorganic barrier layers can also be used. Other types of materials that can serve as a substrate to support the cells are also useful.

In one embodiment, the OLED cells comprise one or more organic layers 202 sandwiched between lower and upper electrodes. In one embodiment, the lower electrodes 204 are anodes and the upper electrodes 206 are cathodes. Forming lower electrodes that are cathodes and upper electrodes that are anodes is also useful. The organic layers are fabricated from organic compounds that include, for example, conjugated polymers, low molecular materials, oligomers, starburst compounds or dendrimer materials. Such materials include tris-(8-hydroxyquinolate)-aluminum (Alq), poly(p-phenylene vinylene) (PPV) or polyfluorene (PF). Other types of functional organic layers, including fluorescence or phosphorescence-based layers, are also useful. The thickness of the organic layer or layers is typically about 2-200 nm.

The anodes are formed from a conductive material. In one embodiment, the conductive material comprises a transparent conductive material such as indium-tin-oxide (ITO). Other transparent conductive materials, for example, indium-zinc-oxide, zinc-oxide or tin-oxide, are also useful. In one embodiment, the cathodes comprise, for example, low work function metals such as lithium (Li), calcium (Ca), magnesium (Mg), aluminum (Al), silver (Ag) and/or barium (Ba), or a mixture or alloy thereof. These metals are highly reactive with water and gaseous content in the atmosphere and must be protected to provide reliability and prolong the useful life span of the device. A thin electron-injecting layer may be provided between the cathode metal and the organic layer for improving, for example, the drive voltage and luminescence efficiencies. The electron-injecting layer comprises, for example, a metal or alloy, or a dielectric compound. These include CsF, Cs₂O, NaF, MgF₂, NaCl, KCl, K₂0 or RbCl.

Various deposition techniques, such as thermal evaporation, may be used to deposit the electrodes. In one embodiment, the electrodes are patterned as strips in, for example, passive-matrix display applications. In one embodiment, pillars 212 are provided on the substrate surface to pattern the device layers as desired to create separate OLED cells. Other methods of patterning the device layers, including photolithography and etching, are also useful.

Typically, the upper and lower electrodes are patterned in first and second directions that are orthogonal to each other. The intersections of the upper and lower electrodes form the OLED cells or pixels. Pixels are addressed by applying a voltage to corresponding rows and columns. Alternatively, the OLED display comprises an active-matrix display. The active-matrix display comprises pixels that are independently addressed by thin-film-transistors (TFTs) and capacitors formed in an electronic backplane. Bond pads or electrical contacts 207 are electrically coupled to the cathodes and anodes.

A cap 216 is provided to hermetically seal the device. The cap, in one embodiment, comprises glass. Other materials, such as metal, ceramic or plastics, can also be used. The cap can be preformed using various techniques, such as etching or stamping, depending on the type of material used. Alternatively, the cap can be a substrate having support posts formed thereon. The support post can be formed by depositing a layer of material and patterning it. Various types of materials, including photosensitive and non-photosensitive materials, such as resist, polyimide, silicon dioxide, can be used. Preferably, the material used is non-conductive. Depending on whether a photosensitive or non-photosensitive material is used, the layer is directly or indirectly patterned with a mask layer. Alternatively, the posts can be formed by selective deposition using, for example, a shadow mask.

In one embodiment, the cap is mounted onto a bonding region of the substrate. In one embodiment, a protective layer can be provided in the bonding region to protect the layers beneath. In a preferred embodiment, the protective layer comprises an insulating material. The use of an insulating material is useful to prevent shorting of conducting lines which provide electrical access to the device. For some applications, a dielectric protective layer may be required in the bonding region to prevent conductive lines on the substrate in the bonding region from being shorted when a conductive cap or conductive post is used. The protective layer comprises, for example, photoresist or photosensitive polyimide. The use of protective layer in the bonding region is described in copending patent application “Improved Encapsulation for Electroluminescent Devices”, U.S. Ser. No. 10/142,208 (attorney docket number 12205/16) filed on May 7, 2002, which is herein incorporated by reference for all purposes. Alternatively, other dielectric materials, such as silicon oxide, silicate glass, or silicon nitride, are also useful. If an insulating material is not required, a conductive material can be used to form the protective layer.

In accordance to the invention, a layer of getter material 208 is provided to protect the active components from degradation caused by moisture and reactive gases such as oxygen. In one embodiment of the invention, the layer of getter material is deposited directly on the active region, covering the active components. By overcoating the active components, the getter layer advantageously encapsulates them, at the same time absorbing the surrounding water and gases.

The getter material can be deposited using various techniques. In one embodiment, the getter material is deposited by evaporation, such as thermal or electron beam. Sputtering techniques can also be used to deposit the getter material. Preferably, the getter material is deposited by flash evaporation. Flash evaporation techniques are described in, for example, concurrently filed patent application titled “Method of Fabricating Electronic Devices” U.S. Ser. No. ______ (attorney docket number 02P13934US), which is herein incorporated by reference for all purposes.

In one embodiment, the getter material comprises alkaline earth metals. Alkaline earth metals include, for example, aluminum (Al), magnesium (Mg), zirconium (Zr), calcium (Ca), tantalum (Ta) or barium (Ba). Preferably, the getter material comprises barium. It has been found that alkaline earth metals are constantly reactive, which prevents the formation of mechanically stable oxide films on the surface that may inhibit further sorption. The getter material may be deposited directly in the active region without packaging and separation from the device layers. This results in a reduction in device thickness, higher efficiency in the fabrication process and lower manufacturing costs. In one embodiment, mass production using roll-to-roll production (also known as “web” processing) is employed, where the getter material and other device layers are continuously or semi-continuously deposited on a flexible substrate translated between two reels.

In another embodiment, a getter layer can also be formed on the inner surface of the cap. This advantageously increases the volume of getter material which can be used to absorb the atmospheric elements which have penetrated the encapsulation.

In one embodiment, pillars 212 are provided on the substrate surface to pattern the device layers as desired to create separate OLED cells. For example, the pillars are arranged in the second direction to pattern the upper electrode layer to form an array of OLED cells. Pillars which create other patterns for the upper electrodes are also useful. OLED cells are located between the pillars where the upper electrodes overlap the lower electrodes.

The pillars serve to pattern the organic, electrode and getter layers during deposition to form distinct or separate portions between the pillars and on the top of the pillars. The profile of the pillars, in one embodiment, comprises an undercut, which results in structures wider at the top than at the bottom. The profile of the pillars, in one embodiment, comprises tapered sides to provide the undercut. The taper angle is, for example, about 30-75 degrees from horizontal. Other types of profiles, such as t-shaped profiles, are also useful. The height of the pillars is about 1-10 μm and preferably about 2-5 μm.

The pillars typically comprise a resist or resin. Various patterning methods such as photolithography, etching and electron curing may be used to form pillars with the desired cross-section. Such methods are described in, for example, copending patent application “Improved Patterning of Electrodes in OLED Devices with Shaped Pillars”, U.S. Ser. No. 09/989,363 (attorney docket number 01P20326US), which is herein incorporated by reference for all purposes.

In one embodiment, the total thickness of the organic, upper electrode and getter layers is less than or equal to the height of the pillars to prevent electrical shorting. Generally, the thickness of the getter layer depends on the thicknesses of the device layers and the type of OLED devices fabricated. In one embodiment, the thickness of the getter layer is about 1-3 μm. Alternatively, if pillars are not used to pattern the device layers in, for example, active-matrix applications, a thicker getter layer may be used. The thickness of the getter layer is, for example, about 30 μm.

Bond pads or electrical contacts 207 formed to provide electrical access to the OLED cells. In addition, a cap 216 is further provided to hermetically encapsulate the OLED device. The cap, in one embodiment, comprises glass. Other materials, such as metal, ceramic or plastics, can also be used.

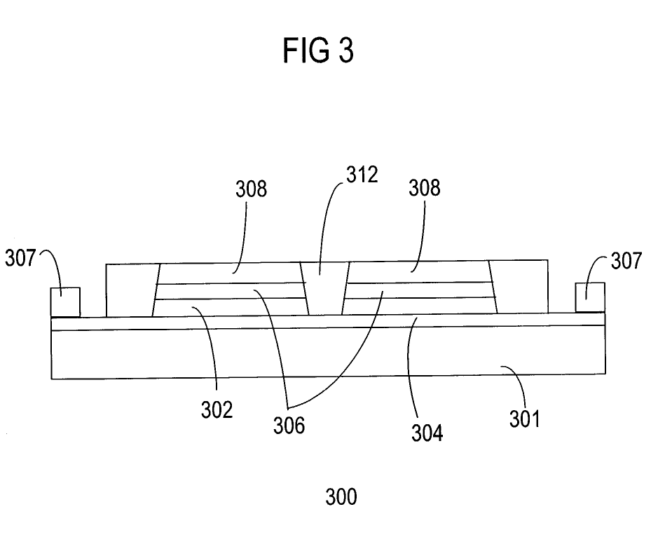

FIG. 3 shows another embodiment of the invention. The OLED device 300 comprises a substrate 301 on which active components are formed in the active region. In one embodiment, the substrate comprises a transparent material, such as glass or plastic. In one embodiment, the substrate comprises a flexible material, such as a plastic film for forming a flexible device. The active components comprise one or more organic layers 302 sandwiched between lower and upper electrodes (304 and 306). A layer of getter material 308 is deposited in the active region to protect the OLED cells from degradation. The getter layer seals the OLED cells and absorbs the surrounding moisture and gases. In one embodiment, the getter material comprises alkaline earth metals, preferably barium.

Pillars 312 are provided to pattern the device layers as desired to create separate OLED cells. The pillars serve to pattern the device layers during deposition to form distinct or separate portions between the pillars and on the top of the pillars. In one embodiment, the total thickness of the organic, upper electrode and getter layers is about equal to the height of the pillars to prevent electrical shorting. Generally, the thickness of the getter layer depends on the thicknesses of the device layers and the type of OLED devices fabricated. In one embodiment, the thickness of the getter layer is about 1-3 μm.

In one embodiment, unwanted portions of the device layers above the pillars are selectively removed by, for example, a polishing process. Other techniques, such as etching, scratching, or laser ablation, can also be used to selectively remove portions of the device layers. Bond pads or electrical contacts 307 are coupled to the cathodes and anodes to provide electrical access.

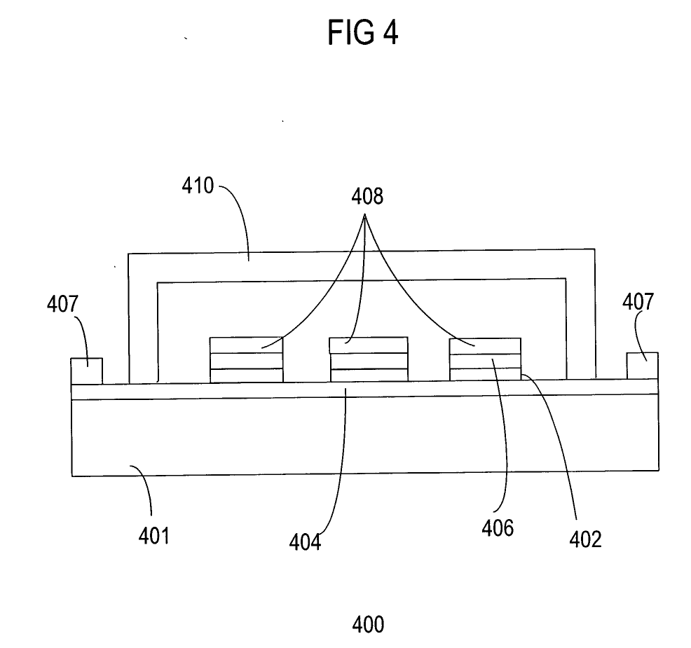

FIG. 4 shows another embodiment of the invention. The OLED device 400 comprises a substrate 401 on which at least one OLED cell is formed. The OLED cells comprise one or more organic layers 402 sandwiched between lower and upper electrodes (404 and 406). In one embodiment, the lower electrodes 404 are anodes and the upper electrodes 406 are cathodes. The anodes and cathodes are formed as strips in respective first and second directions. Typically, the first and second directions are orthogonal to each other. The intersections of the upper and lower electrode strips form OLED cells.

In accordance to the invention, a layer of getter material 408 is provided to protect the device layers from degradation. The getter material overcoats the cells and forms a barrier against residual moisture and gases. In one embodiment, the getter material comprises alkaline earth metals, preferably barium. The lower and upper electrode layers (404 and 406), and the getter layer 408 may be patterned as desired to form the cells. Various patterning techniques, such as shadow masking, photolithography (with wet or dry etching), laser ablation, or lift-off techniques (wet or dry resists), can be used.

Bond pads or electrical contacts 407 are electrically coupled to the cathodes and anodes. In addition, a cap 410 is further provided to hermetically seal the OLED device.

While the invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

What is claimed is:

1. A method of encapsulating an organic device, comprising:
providing a substrate having an active region defined thereon, the active region comprising an active component;
covering the active component with a getter layer, the getter layer comprising an alkaline earth metal; and
mounting the substrate with a cap to seal the device.

2. The method of claim 1 wherein the active component comprises at least one OLED cell to form an OLED device.

3. The method of claim 1 wherein the substrate comprises a transparent material.

4. The method of claim 1 wherein the substrate comprises a flexible material.

5. The method of claim 4 wherein the active component comprises at least one OLED cell to form an OLED device.

6. The method of claim 5 wherein the step of covering the active component with a getter layer comprises depositing the getter layer using evaporation or sputtering techniques.

7. The method of claim 6 wherein the getter layer comprises barium.

8. The method of claim 5 wherein the OLED cell comprises at least one organic layer formed between a lower electrode layer and an upper electrode layer.

9. The method of claim 8 further comprises providing pillars on the substrate for patterning the upper electrode layer and the getter layer.

10. The method of claim 9 wherein the getter layer comprises barium.

11. The method of claim 9 wherein the pillars comprise a profile with an undercut.

12. The method of claim 9 wherein the organic layer, the upper electrode layer and the getter layer comprise a total thickness less than or equal to a height of the pillars.

13. A method of encapsulating an OLED device, comprising:
providing a substrate having a plurality of OLED cells, the OLED cells comprising at least one organic layer formed between lower and upper electrode layers;
sealing the cells with a getter layer, the getter layer comprising an alkaline earth metal; and
providing pillars on the substrate for patterning the upper electrode layer and the getter layer.

14. The method of claim 13 wherein the getter layer comprises barium.

15. The method of claim 13 wherein the pillars comprise a profile with an undercut.

16. The method of claim 15 wherein the organic layer, the upper electrode layer and the getter layer comprise a total thickness about equal to a height of the pillars.

17. The method of claim 16 further comprising a step of selectively removing unwanted portions of the getter layer, the upper electrode layer and the organic layer above the pillars.

18. An organic device comprising:
a substrate having an active region defined thereon, the active region comprising an active component; and
a getter layer covering the active component, the getter layer comprising an alkaline earth metal.

19. The device of claim 18 wherein the active component comprises at least one OLED cell to form an OLED device.

20. The device of claim 19 further comprises a cap mounted on the substrate to seal the device.

21. The device of claim 20 wherein the substrate comprises a transparent material.

22. The device of claim 20 wherein the substrate comprises a flexible material.

23. The device of claim 20 wherein the getter layer comprises barium.

24. The device of claim 18 wherein the getter layer comprises barium.
